(19) United States
(12) Patent Application Publication
(10) Pub. No.: US 2026/0072467 A1
(43) Pub. Date: Mar. 12, 2026

(54) PROCESSOR-BASED SYSTEM CONFIGURED TO DYNAMICALLY MITIGATE PEAK CURRENT DEMAND OF A SHARED POWER RAIL POWERING A MEMORY SYSTEM

(71) Applicant: QUALCOMM Incorporated, San Diego, CA (US)

(72) Inventors: Dipti Ranjan Pal, Irvine, CA (US); Aseem Pandey, San Diego, CA (US); Manish Goel, San Diego, CA (US); Shih-Hsin Jason Hu, San Diego, CA (US)

(21) Appl. No.: 18/826,349

(22) Filed: Sep. 6, 2024

(51) Int. Cl. G06F 1/08; G06F 11/30; G11C 5/14

(52) U.S. Cl. CPC G06F 1/08; G06F 11/3058; G11C 5/14

(57) ABSTRACT

Aspects disclosed in the detailed description include a processor-based system configured to dynamically mitigate peak current demand of a shared power rail powering a memory system. The processor-based system includes a plurality of processing units which utilize the memory system. The memory system is powered by the shared power rail. The processor-based system monitors a current demand of the shared power rail from the plurality of processing units, determines whether the current demand for the shared power rail exceeds a peak threshold, and, in response to the current demand exceeding the peak threshold, throttle one or more operating parameters of at least one of the plurality of processing units to reduce or slow access to the memory system and, thus, the current demand over the shared power rail.

### TECHNICAL FIELD

The field of this disclosure relates to power and clock management in a processor-based system.

### BACKGROUND

Microprocessors, also known as processing units (PUs), perform computational tasks in a wide variety of applications. One type of conventional microprocessor or PU is a central processing unit (CPU). Another type of microprocessor or PU is a dedicated processing unit known as a graphics processing unit (GPU). A GPU is designed with specialized hardware to accelerate the rendering of graphics and video data for display. A GPU may be implemented as an integrated element of a general-purpose CPU or as a discrete hardware element that is separate from the CPU. Another type of PU is a dedicated processing unit known as a neural processing unit (NPU). An NPU is designed with specialized hardware to perform several key functions in analyzing and processing signals from a nervous system. An NPU includes specialized computing circuits that can be particularly suited for machine learning applications and running various artificial intelligence (AI) applications.

A PU(s) executes software instructions that instruct a processor to fetch data from a location in memory and to perform one or more processor operations using the fetched data. The result may then be stored in memory. For example, this memory can be a cache memory local to the PU, a shared local cache among PUs in a PU block, a shared cache among multiple PU blocks, and/or a system memory in a processor-based system. Cache memory, which can also be referred to as just “cache,” is a smaller, faster memory that stores copies of data stored at frequently accessed memory addresses in a main memory or higher-level cache memory to reduce memory access latency. Thus, a cache memory can be used by a PU to reduce memory access times.

When data requested by a memory read request is present in a cache memory (i.e., a cache “hit”), system performance may be improved by retrieving the data from the cache instead of slower access system memory. Conversely, if the requested data is not found in the cache (resulting in a cache “miss”), the requested data then must be read from a higher-level cache memory, and if a miss occurs in the higher-level cache memory, the requested data then must be read from a system memory. Frequent occurrences of cache misses result in system performance degradation that could negate the advantage of using the cache in the first place. Shared cache memory including local cache memory is powered by a power management integrated circuit (IC) (PMIC).

### SUMMARY OF THE DISCLOSURE

Aspects disclosed in the detailed description include a processor-based system configured to dynamically mitigate peak current demand of a shared power rail powering a memory system. Related apparatus and methods are also disclosed. The processor-based system includes a plurality of processing units which utilize the memory system. The memory system is powered by the shared power rail. The processor-based system monitors a current demand of the shared power rail from the plurality of processing units, determines whether the current demand for the shared power rail exceeds a peak threshold, and, in response to the current demand exceeding the peak threshold, throttles one or more operating parameters of at least one of the plurality of processing units to reduce or slow access to the memory system and thus, the current demand over the shared power rail. In this regard, the processor-based system advantageously manages the current demand of a shared power rail when deploying the processor-based system in a device which constrains the memory system to be powered by the shared power rail. For example, when the processor-based system is deployed in an extended reality device such as smart glasses or an artificial intelligence (AI) pin, the extended reality device has size constraints which, in turn, impose limits on a power management integrated circuit (PMIC) which powers various components of the processor-based system. Some limits of the PMIC may include the number of different power rails it may supply to the processor-based system, the size of a buck converter within the PMIC which may limit the power supplied to a processor-based system, as well as the number of different power rails supplied to the processor-based system.

In an aspect, a processor-based system is disclosed. The processor-based system includes a memory system. The processor-based system also includes a shared power rail configured to supply power to the memory system. The processor-based system also includes a plurality of processing units. Each of the plurality of processing units is configured to access the memory system. The processor-based system is configured to monitor a current demand for the shared power rail from the plurality of processing units. The processor-based system is also configured to determine whether the current demand for the shared power rail exceeds a peak threshold. In response to the current demand exceeding the peak threshold, the processor-based system is also configured to throttle one or more operating parameters of at least one of the plurality of processing units to reduce the current demand over the shared power rail.

In another aspect, method for dynamically mitigating peak current demand of a shared power rail powering a memory system is provided. The method includes monitoring a current demand for the shared power rail from a plurality of processing units The method also includes determining whether the current demand for the shared power rail from the plurality of processing units exceeds a peak threshold. The method also includes, in response to the current demand exceeding the peak threshold, throttling one or more operating parameters of at least one of the plurality of processing units to reduce the current demand over the shared power rail.

### BRIEF DESCRIPTION OF THE FIGURES

FIG. 1 is a block diagram of an exemplary processor-based system that includes a plurality of processing units and a memory system wherein the processor-based system is configured to dynamically mitigate peak current demand of a shared power rail powering a memory system;

FIG. 2 is a close-up view of the processor-based system in FIG. 1 including an exemplary power management control unit, such as the power management control unit in the exemplary processor-based system in FIG. 1, wherein at least three PUs in FIG. 1 include a CPU, GPU, and NPU, and wherein the PMIC of FIG. 1 is configured to measure the current demand of the shared power rail in FIG. 1;

FIG. 3 is a close-up view of the processor-based system in FIG. 1 including another exemplary power management control unit, such as the power management control unit in the exemplary processor-based system in FIG. 1, wherein the exemplary power management control unit is configured to estimate the current demand of the shared power rail in FIG. 1;

FIG. 4 is a close-up view of the processor-based system in FIG. 1 including the exemplary power management control unit in FIG. 3;

FIGS. 5A-5C illustrate an exemplary estimation look-up table (LUT) for each of the processing units shown in FIG. 3, wherein the exemplary estimation LUTs are configured to store an estimated current demand of the shared power rail by each of the processing units based on one or more current operating parameters for each of the processing units;

FIG. 5A shows an exemplary estimation LUT configured to store the estimated current demand of the shared power rail by the CPU in FIG. 2 based on one or more current operating parameters of the CPU;

FIG. 5B shows an exemplary estimation LUT configured to store the estimated current demand of the shared power rail by the GPU in FIG. 2 based on one or more current operating parameters of the GPU;

FIG. 5C shows an exemplary estimation LUT configured to store the estimated current demand of the shared power rail by the NPU in FIG. 2 based on one or more current operating parameters of the NPU;

FIGS. 6A-6C illustrate an exemplary filter LUT for each of the processing units shown in FIG. 2, wherein the exemplary filter LUTs are configured to store whether to throttle one or more of the processing units shown in FIG. 2;

FIG. 6A shows an exemplary filter LUT configured to store whether to throttle the CPU in FIG. 2 based on one or more current operating parameters of the CPU;

FIG. 6B shows an exemplary filter LUT configured to store whether to throttle the GPU in FIG. 2 based on one or more current operating parameters of the GPU;

FIG. 6C shows an exemplary filter LUT configured to store whether to throttle the NPU in FIG. 2 based on one or more current operating parameters of the NPU;

FIGS. 7A-7C illustrate an exemplary mitigation look-up table (LUT) for each of the processing units shown in FIG. 2, wherein the exemplary mitigation LUTs are configured to store mitigations of how to throttle the at least one of the plurality of processing units being indicated to be throttled in the filter LUT shown in FIGS. 6A-6C;

FIG. 7A shows an exemplary mitigation LUT configured to store mitigations of how to throttle the CPU in FIG. 2 based on one or more current operating parameters of the CPU;

FIG. 7B shows an exemplary mitigation LUT configured to store mitigations of how to throttle the GPU in FIG. 2 based on one or more current operating parameters of the GPU;

FIG. 7C shows an exemplary mitigation LUT configured to store mitigations of how to throttle the NPU in FIG. 2 based on one or more current operating parameters of the NPU;

FIG. 8 is a flowchart illustrating an exemplary process for dynamically mitigating peak current demand of a shared power rail powering a memory system, wherein the memory system is deployed in a processor-based system including the processor-based system in FIG. 1; and

FIG. 9 is a block diagram of an exemplary processor-based system that can include the processor-based system including, but not limited to, the processor-based system of FIG. 1 and according to exemplary process of FIG. 8 which is configured to dynamically mitigate peak current demand of a shared power rail powering a memory system.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include a processor-based system configured to dynamically mitigate peak current demand of a shared power rail powering a memory system. Related apparatus and methods are also disclosed. The processor-based system includes a plurality of processing units which utilize the memory system. The memory system is powered by the shared power rail. The processor-based system monitors a current demand of the shared power rail from the plurality of processing units, determines whether the current demand for the shared power rail exceeds a peak threshold, and, in response to the current demand exceeding the peak threshold, throttles one or more operating parameters of at least one of the plurality of processing units to reduce or slow access to the memory system and thus, the current demand over the shared power rail. In this regard, the processor-based system advantageously manages the current demand of a shared power rail when deploying the processor-based system in a device which constrains the memory system to be powered by the shared power rail.

For example, when the processor-based system is deployed in an extended reality device such as smart glasses or an artificial intelligence (AI) pin, the extended reality device has size constraints which, in turn, impose limits on a power management integrated circuit (PMIC) which powers various components of the processor-based system. Some limits of the PMIC may include the number of different power rails it may supply to the processor-based system, the size of a buck converter within the PMIC which may limit the power supplied to a processor-based system, as well as the number of different power rails supplied to the processor-based system.

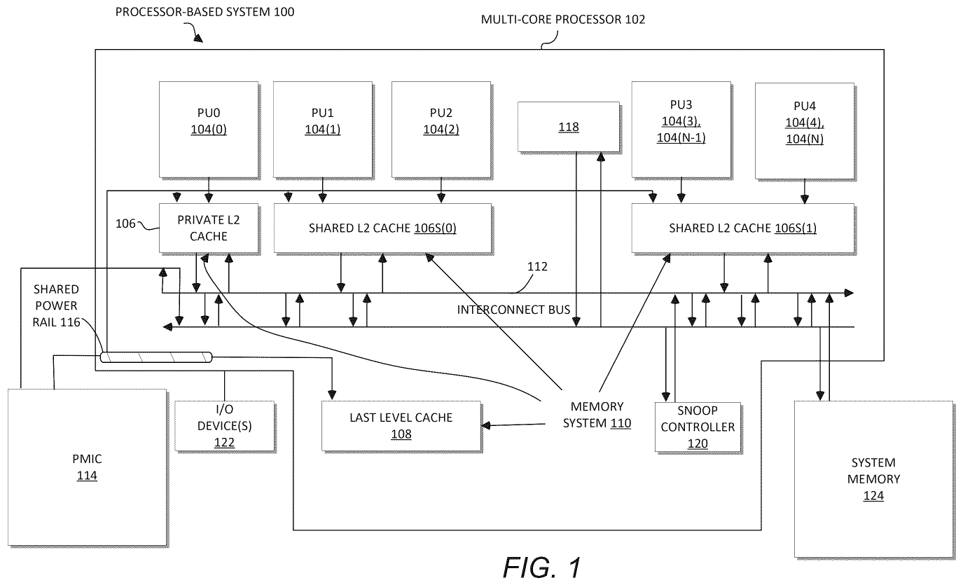

In this regard, FIG. 1 is a block diagram of an exemplary processor-based system 100 that includes a plurality of processing units and a memory system wherein the processor-based system is configured to dynamically mitigate peak current demand of a shared power rail powering a memory system. Before discussing these aspects, other exemplary aspects of the processor-based system 100 are first described below.

The processor-based system 100 includes a multiple (multi-) core processor 102 that includes multiple PUs 104(0)-104(N) and a hierarchical memory system. As part of the hierarchical memory system, for example, PU 104(0) includes a private local cache memory 106, which may be a Level 2 (L2) cache memory. PUs 104(1), 104(2) and PUs 104(N-1), 104(N) are configured to interface with respective local shared cache memories 106S(0)-106S(1), which may also be L2 cache memories for example. If a data read request requested by a PU 104(0)-104(N) results in a cache miss to the respective cache memories 106, 106S(0)-106S(1), the read request may be communicated to a next-level cache memory, which in this example is a shared system cache memory 108, also referred to as a last level cache 108. For example, the last level cache 108 may be a Level 3 (L3) cache memory. The cache memory 106, the local shared cache memories 106S(0)-106S(1), and the shared system cache memory 108 are part of a hierarchical memory system 110. An interconnect bus 112, which may be a coherent bus, is provided that allows each of the PUs 104(0)-104(N) to access the shared cache memories 106S(0)-106S(1) (if shared to the PU 104(0)-104(N)), the shared system cache memory 108, and other shared resources coupled to the interconnect bus 112.

A PMIC 114 supplies power to the processor-based system 100. In particular, the PMIC 114 supplies power to the memory system 110 over a shared power rail 116. The PMIC 114 also provides power to PU0-PU4 but the corresponding power rails are not shown for simplicity.

The processor-based system 100 may be a heterogeneous processor-based system. For example, PU0 104(0) may be an NPU, PU1 104(1) and PU2 104(2) may each be a CPU, and PU3 104(3) and PU4 104(4) may each be a GPU.

The processor-based system 100 in FIG. 1 includes a power management control circuit 118. The power management control circuit 118 communicates with the PUs 104(0)-104(4) and the PMIC 114 over the interconnect bus 112 in the multi-core processor 102. The power management control circuit 118 is configured to monitor a current demand of the shared power rail 116 from the processing units 104(0)-104(4) accessing the memory system 110, determine whether the current demand of the shared power rail 116 exceeds a peak threshold, and, in response to the current demand exceeding the peak threshold, throttle one or more operating parameters of at least one of the processing units 104(0)-104(4) to reduce the current demand over the shared power rail 116.

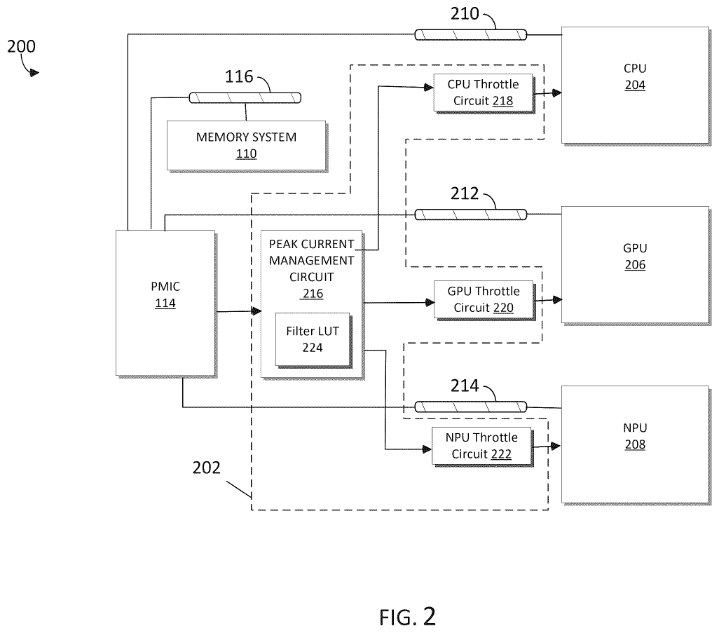

In particular, the power management control circuit 118 that, in response to the current demand exceeding the peak threshold, throttles one or more operating parameters of at least one of the processing units 104(0)-104(4) to reduce the current demand over the shared power rail 116, is further configured into a two-stage approach. One stage is for the power management control circuit 118 to determine whether the one or more operating parameters of the at least one of the processing units 104(0)-104(4) should be throttled. A second stage occurs, in response to the one or more operating parameters of the at least one of the processing units 104(0)-104(4) being determined to be throttled, the power management control circuit 118 sets the one or more operating parameters of the at least one of the processing units 104(0)-104(4) being determined to be throttled to a reduced level based on current operating parameters of the at least one of the processing units 104(0)-104(4). The power management control circuit 118 will be discussed in more detail in connection with FIGS. 2-4.

With continuing reference to FIG. 1, the processor-based system 100 in this example also includes a snoop controller 120, which is also coupled to the interconnect bus 112. The snoop controller 120 is a circuit that monitors or snoops cache memory bus transactions on the interconnect bus 112 to maintain cache coherency among the cache memories 106, 106S(0)-106S(1), 108 in the memory system 110. Other shared resources that can be accessed by the PUs 104(0)-104(4) through the interconnect bus 112 can include input/output (I/O) devices 122 and a system memory 124 (e.g., a dynamic random access memory (DRAM)). If a cache miss occurs for a read request issued by a PU 104(0)-104(4) in each level of the cache memories 106, 106S(0)-106S(1), 108 accessible for the PU 104(0)-104(4), the read request is serviced by the system memory 124, and the data associated with the read request is installed in the cache memories 106, 106S(0)-106S(1), 108 associated with the requesting PU 104(0)-104(4).

FIG. 2 is a close-up view 200 of the processor-based system in FIG. 1 including an exemplary power management control unit 202, such as the power management control circuit 118 in the exemplary processor-based system 100 in FIG. 1, wherein at least three of the PUs 104(0)-104(N) in FIG. 1 include a CPU 204, GPU 206, and NPU 208, and wherein the PMIC 114 is configured to measure the current demand of the shared power rail in FIG. 1. The PMIC 114 also supplies power to the CPU 204 over a power rail 210, the GPU 206 over a power rail 212, and the NPU 208 over a power rail 214. The power management control unit 202 includes a peak current management circuit 216, a CPU throttle circuit 218, a GPU throttle circuit 220, and an NPU throttle circuit 222. The peak current management circuit 216 includes a filter look-up table (LUT) 224.

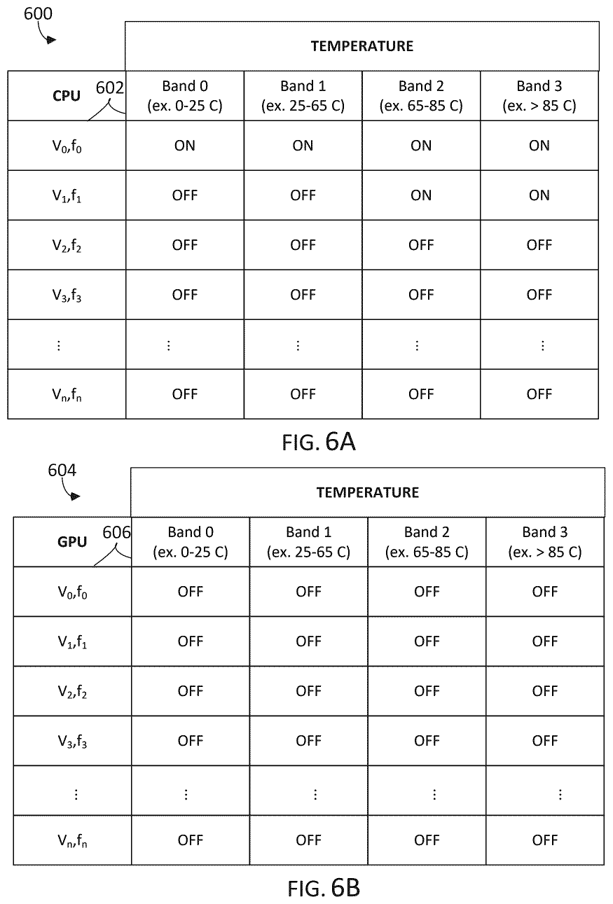

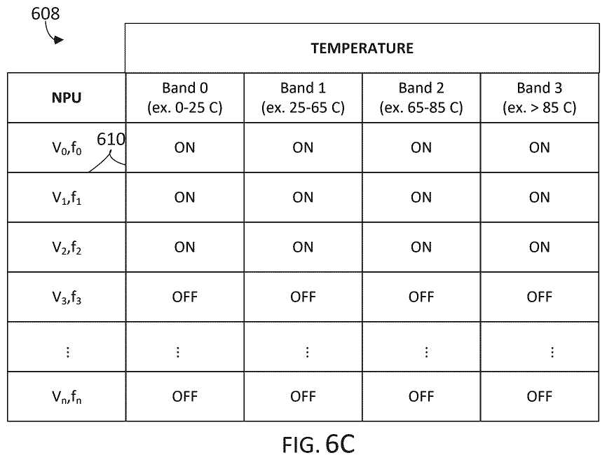

The filter LUT 224 is configured to store whether to throttle one or more of the CPU 204, GPU 206, and NPU 208 units based on one or more current operating parameters for each respective CPU 204, GPU 206, and NPU 208. The one or more current operating parameters include an operating voltage for each respective CPU 204, GPU 206, and NPU 208, an operating frequency for each respective CPU 204, GPU 206, and NPU 208, and a current temperature for each respective CPU 204, GPU 206, and NPU 208. The peak current management circuit 216 receives the one or more current operating parameters from each respective CPU 204, GPU 206, and NPU 208. An exemplary filter LUT, such as the filter LUT 224, will be described in connection with FIGS. 6A-6C.

In operation, the PMIC 114 measures the current demand on the shared power rail 116 by measuring a present voltage being supplied to the shared power rail 116. For example, the PMIC 114 may utilize a small series of 1 meta-ohm resistors and measure the voltages across the series using an operational amplifier and calculating the current demand by dividing the measured voltage by the resistance of the series of resistors. The PMIC 114 reports a peak event message to the peak current management circuit 216 whenever the present voltage exceeds a peak threshold. The peak threshold may be stored in a programmable register in the PMIC 114. The peak current management circuit 216, in response to the peak event message, performs a look up into the filter LUT 224 based on the one or more current operating parameters for each of the CPU 204, GPU 206, and NPU 208 to receive an indication stored in the filter LUT 224 for each of the CPU 204, GPU 206, and NPU 208. Each indication will indicate whether or not a respective CPU 204, GPU 206, and/or NPU 208 should have its respective operating parameters throttled. In this regard, for those indications where a respective processing unit should be throttled, the peak current management circuit 216 triggers a corresponding throttle circuit. For example, if one of the indications indicated the CPU 204 should be throttled, the peak current management circuit 216 triggers the CPU throttle circuit 218 to determine how to throttle the CPU 204. Likewise, if one of the indications indicated the GPU 206 should be throttled, the peak current management circuit 216 triggers the GPU throttle circuit 220 to determine how to throttle the GPU 206. Similarly, if one of the indications indicated the NPU 208 should be throttled, the peak current management circuit 216 triggers the NPU throttle circuit 222 to determine how to throttle the NPU 208.

In this regard, by utilizing the filter LUT 224, a respective throttle circuit is only triggered when a subsequent throttle will take place reducing the triggers in the processor-based system.

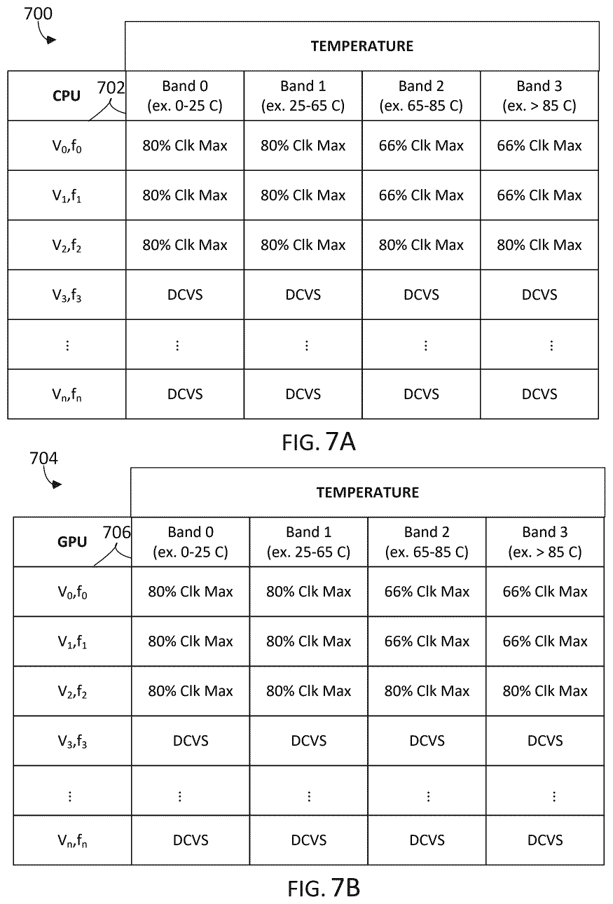

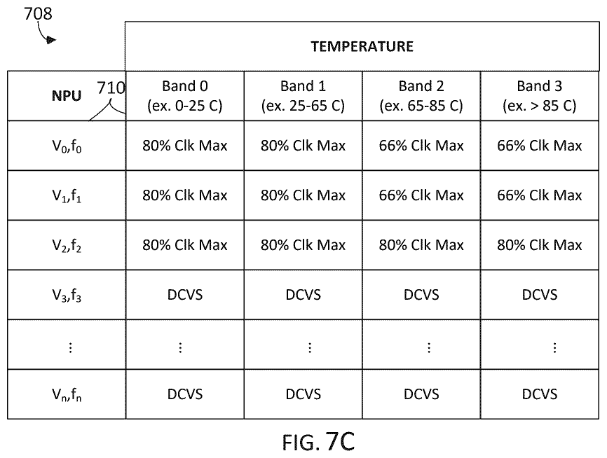

A throttle circuit, such as the CPU throttle circuit 218, GPU throttle circuit 220, or NPU throttle circuit 222, employs a mitigation LUT to determine how to throttle the respective processing unit. The mitigation LUT is configured to store a plurality of mitigations of how to throttle the at least one of the CPU 204, GPU 206, and NPU 208 being indicated to be throttled in the filter LUT 224 based on the one or more current operating parameters corresponding to the at least one of the CPU 204, GPU 206, and NPU 208 being indicated to be throttled. In response to the at least one of throttle circuits, such as the CPU throttle circuit 218, GPU throttle circuit 220, and/or NPU throttle circuit 222, being triggered, the corresponding throttle circuit(s) is configured to look up a mitigation in the mitigation LUT corresponding to a respective processing unit, such as the CPU 204, GPU 206, and NPU 208, of the at least one of the plurality of processing units being indicated to be throttled based on the one or more current operating parameters for the respective processing unit. Exemplary mitigation LUTs for a CPU, GPU, and NPU, such as the CPU 204, a GPU 206, and an NPU 208, will be discussed in connection with FIGS. 7A-7C.

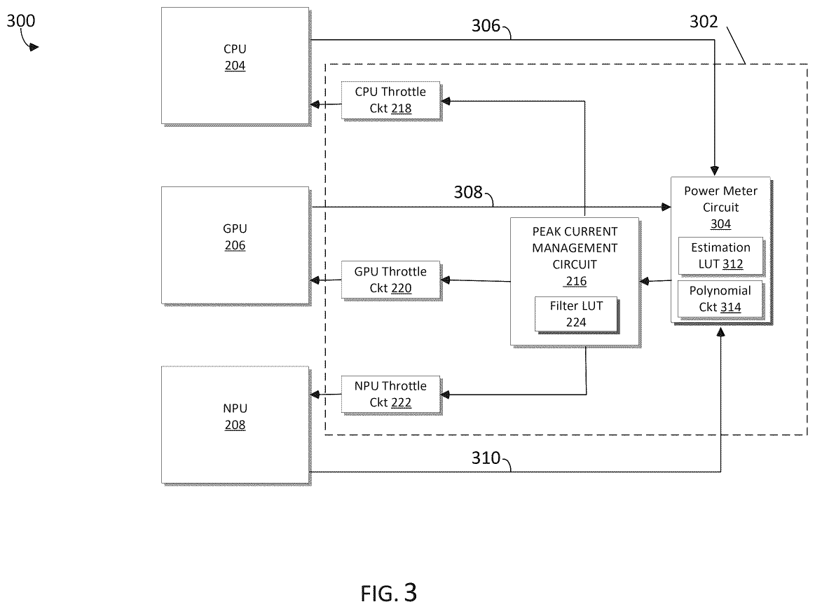

FIG. 3 is a close-up view 300 of the processor-based system in FIG. 1 including another exemplary power management control unit 302, such as the power management control circuit 118 in the exemplary processor-based system in FIG. 1, wherein the exemplary power management control unit 302 is configured to estimate the current demand of the shared power rail in FIG. 1. Common elements between the close-up view 300 in FIG. 3 and the close-up view 200 in FIG. 2 are shown with common element numbers. The power management control unit 302 includes a power meter circuit 304. The power meter circuit 304 receives current operating parameters from the CPU 204, GPU 206, and NPU 208 over paths 306, 308, and 310, respectively. The current operating parameters include the current operating voltage, current operating clock frequency, and/or current temperature of the respective processing units 204, 206, and 208.

The power meter circuit 304 includes two approaches for estimating the current demand of the memory system 110 by the respective processing units 204, 206, and 208. In one approach, the power meter circuit 304 includes an estimation LUT 312. The estimation LUT 312 is configured to store an estimated current demand for each of the respective processing units, such as the CPU 204, GPU 206, and NPU 208 based on the current operating parameters for each of the plurality of processing units. In operation, the power meter circuit 304 is configured to estimate the current demand on the shared power rail by looking up the estimated current demand stored in the estimation LUT 312 based on the current operating parameters. The estimated current demand may be an aggregation of an estimated current demand for each processing unit such as the CPU 204, GPU 206, and NPU 208.

In a second approach, the power meter circuit 304 includes a polynomial circuit 314. The polynomial circuit 314 is configured to calculate an estimated current demand based on one or more current operating parameters for each of the processing units such as the CPU 204, GPU 206, and NPU 208. In operation, the power meter circuit 304 is configured to estimate the current demand on the shared power rail, by inputting the one or more current operating parameters to the polynomial circuit 314 which calculates the current demand. An exemplary polynomial to calculate the estimated current demand for each processing unit, such as the CPU 204, GPU 206, and NPU 208, by the polynomial circuit 314 is as follows:

$$\begin{matrix}{I}_{PU} = {I}_{dynamic} + {I}_{leakage} , where : \\ {I}_{dynamic} = sVf , under workload conditions ,\end{matrix}$$

where:
   V is the current operating voltage of the processing unit,
   f is the current operating frequency of the processing unit, and
   s is a scaling factor for capacitance of the processing unit and an activity
   factor (e.g., the level of circuit switching activity).

$${I}_{leakage} = ( {aV}^{3} + {bV}^{2} + cV + d ) * ( {eT}_{avg}^{3} + {fT}_{avg}^{2} + {gT}_{avg} + h ) * BL ,$$

where
   BL is the baseline leakage for the processing unit,
   T_{avg} is the current operating temperature of the processing unit,
   a, b, c, d are polynomial coefficients for V, and
   e, f, g, h are polynomial coefficients for T.
      The polynomial coefficients a . . . h are determined during a characterization process of the silicon in which the processor-based system 100 is deployed. The results from each of the polynomials corresponding to each of the processing units are summed to determine the estimated current demand.

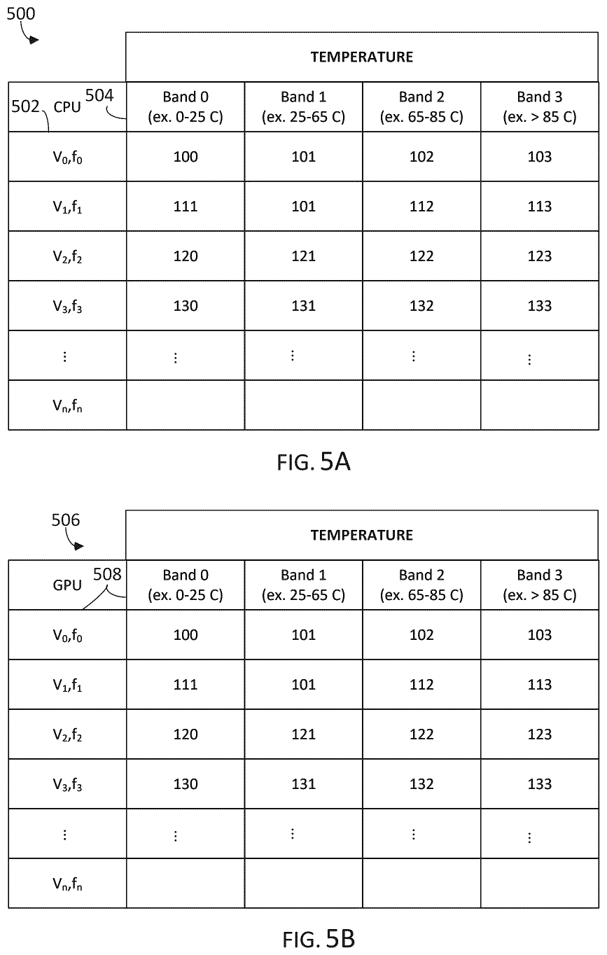

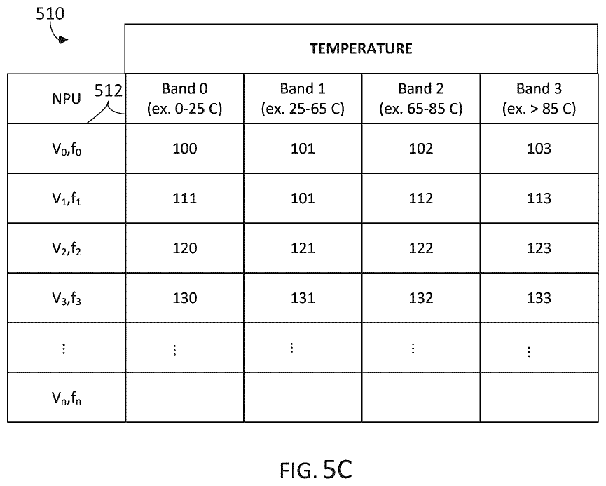

In either approach, if the estimated current demand on the shared power rail equals or exceeds a peak threshold which is stored in a programmable register in the processor-based system 100, the power meter circuit 304 triggers the peak current management circuit 216 to determine whether or not to throttle one or more of the processing units as was described in FIG. 2. Exemplary estimation LUTs for a CPU, GPU, and NPU, such as the CPU 204, a GPU 206, and an NPU 208, will be discussed in connection with FIGS. 5A-5C.

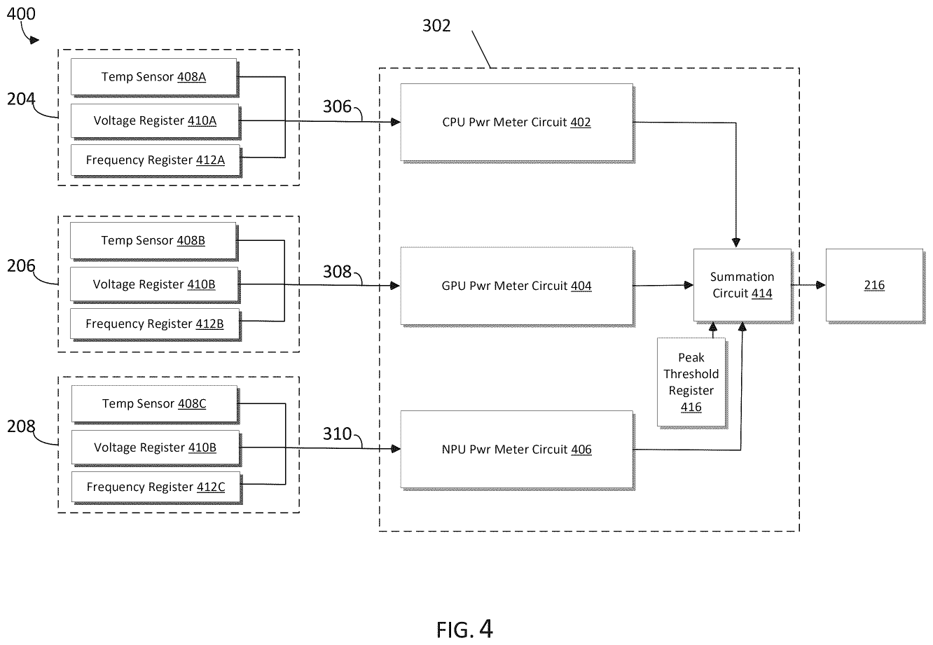

FIG. 4 is a close-up view 400 of the processor-based system in FIG. 1 including the exemplary power management control unit 302 in FIG. 3. Common elements between the close-up view 200 in FIG. 2, the close-up view 300 in FIG. 3, and the close-up view 400 in FIG. 4 are shown with common element numbers. The power management control unit 302 includes a CPU power meter circuit 402, a GPU power meter circuit 404, and an NPU power meter circuit 406. Each of the power meter circuits 402, 404, 406 receives current operating parameters from respective processing units, such as the CPU 204, GPU 206, and NPU 208 over the paths 306, 308, and 310, respectively. Each of the processing units, such as the CPU 204, GPU 206, and NPU 208 include a corresponding temperature sensor such as temperature sensors 408A-408C, a corresponding voltage register such as voltage registers 410A-410C, and a corresponding frequency register such as frequency registers 412A-412C. The corresponding temperature sensor determines the current operating temperature of the corresponding processing unit and reports the current operating temperature to the corresponding power meter circuit such as the CPU power meter circuit 402, GPU power meter circuit 404, and NPU power meter circuit 406. The corresponding voltage register stores the maximum voltage being supplied to the corresponding processing unit. The corresponding frequency register stores the current operating frequency of a clock driving the corresponding processing unit. Each of the power meter circuits including the CPU power meter circuit 402, GPU power meter circuit 404, and NPU power meter circuit 406 receives the corresponding current operating parameters from the corresponding temperature sensor 408A-408C, the corresponding voltage register 410A-410C, and the corresponding frequency register 412A-412C. Each of the power meter circuits 402, 404, and 406 estimates the current demand of the shared power rail 116 by the corresponding processing units 204, 206, and 208, respectively, utilizing a corresponding estimation LUT such as estimation LUTs in FIGS. 5A-5C. The power management control unit 302 also includes a summation circuit 414 which aggregates the estimated current demand for each of the processing units and compares the aggregated estimated current demand to a peak threshold stored in a peak threshold register 416. If the aggregated estimated current demand is equal to or greater than the peak threshold, the summation circuit 414 triggers the peak current management circuit 216 which, in turn, operates as described above.

FIGS. 5A-5C illustrate an exemplary estimation LUT for each of the processing units shown in FIG. 3, wherein the exemplary estimation LUTs are configured to store an estimated current demand of the shared power rail 116 by each of the processing units based on one or more current operating parameters for each of the processing units. FIG. 5A shows an exemplary estimation LUT 500 configured to store the estimated current demand of the shared power rail 116 by the CPU 204 in FIG. 2 based on one or more current operating parameters of the CPU 204. The one or more operating parameters include the voltage, frequency pairs in column 502. The voltage, frequency pairs in column 502 represent the operating voltage of the CPU 204 and the frequency at which the CPU 204 is currently being clocked. The one or more current operating parameters also include a temperature band 504 in which the current temperature of the CPU 204 is operating. In operation, the CPU power meter circuit 402 looks up the current operating parameters from the temperature sensor 408A, voltage register 410A, and frequency register 412A to find a match in the operating voltage and operating frequency pairs along with the temperature band 504 in which the current temperature stored in the temperature sensor 408A resides. The combination of those current operating parameters returns the estimated current demand of the shared power rail 116 by the CPU 204. For example, if the current voltage, frequency pair is V₁,f₁ and the CPU 204 is currently operating at 45° C., the estimated current demand would be 101 milliamps (mA).

FIG. 5B shows an exemplary estimation LUT 506 configured to store the estimated current demand of the shared power rail 116 by the GPU 206 in FIG. 2 based on one or more current operating parameters of the GPU 206. The configuration and layout of the estimation LUT 506 is the same as the estimation LUT 500 in FIG. 5A. Operating parameters 508 include operating voltage, frequency pairs and temperature bands in which the GPU 206 operates. The operating parameters 508 are shown to be the same as those in the estimation LUT 500 but could be different than those in the estimation LUT 500 depending on the operating characteristics of the GPU 206. In operation, the GPU power meter circuit 404 looks up the current operating parameters from the temperature sensor 408B, voltage register 410B, and frequency register 412B to find a match in the operating voltage and operating frequency pairs along with the temperature band in which the current temperature stored in the temperature sensor 408B resides. The combination of those current operating parameters returns the estimated current demand of the shared power rail 116 by the GPU 206.

FIG. 5C shows an exemplary estimation LUT 510 configured to store the estimated current demand of the shared power rail 116 by the NPU 208 in FIG. 2 based on one or more current operating parameters of the NPU 208. The configuration and layout of the estimation LUT 510 is the same as the estimation LUTs 500 and 506 in FIGS. 5A and 5B. Operating parameters 512 include operating voltage, frequency pairs and temperature bands in which the NPU 208 operates. The operating parameters 512 are shown to be the same as those in the estimation LUTs 500 and 506 but could be different than those in the estimation LUTs 500 and 506 depending on the operating characteristics of the NPU 208. In operation, the NPU power meter circuit 406 looks up the current operating parameters from the temperature sensor 408C, voltage register 410C, and frequency register 412C to find a match in the operating voltage and operating frequency pairs along with the temperature band in which the current temperature stored in the temperature sensor 408C resides. The combination of those current operating parameters returns the estimated current demand of the shared power rail 116 by the NPU 208. The summation circuit 414 sums the estimated current demand obtained from each estimation LUT 500, 506, 510 and determines whether the calculated sum equals or exceeds the peak threshold which is stored in the peak threshold register 416.

The estimation LUTs 500, 506, and 510 are programmable and may be programmed when a respective processing unit is initialized such as when the respective processing unit is powered on or is reset.

FIGS. 6A-6C illustrate an exemplary filter LUT for each of the processing units (CPU 204, GPU 206, NPU 208) shown in FIG. 2, wherein the exemplary filter LUTs are configured to store whether to throttle one or more of the processing units shown in FIG. 2.

FIG. 6A shows an exemplary filter LUT 600 configured to store whether to throttle the CPU 204 based on one or more current operating parameters of the CPU 204. The configuration and layout of the filter LUT 600 is the same as the estimation LUTs 500, 506 and 510 in FIGS. 5A-5C. Operating parameters 602 include operating voltage, frequency pairs and temperature bands. The operating parameters 602 are shown to be the same as those in the estimation LUTs 500, 506 and 510 but could be different than those in the estimation LUTs 500, 506 and 510 depending on the operating characteristics of the CPU 204. In operation, the peak current management circuit 216 looks up the current operating parameters from the temperature sensor 408A, voltage register 410A, and frequency register 412A to find a match in the operating voltage and operating frequency pairs along with the temperature band in which the current temperature stored in the temperature sensor 408A resides. The combination of those current operating parameters returns an indication of whether or not (shown as ON or OFF) the CPU 204 should be throttled to reduce current demand by the CPU 204 on the shared power rail 116.

FIG. 6B shows an exemplary filter LUT 604 configured to store whether to throttle the GPU 206 in FIG. 2 based on one or more current operating parameters of the GPU 206. The configuration and layout of the filter LUT 604 is the same as the filter LUT 600 in FIG. 6A. Operating parameters 606 include operating voltage, frequency pairs and temperature bands. The operating parameters 606 are shown to be the same as the operating parameters 602 in the filter LUT 600 but could be different depending on the operating characteristics of the GPU 206. In operation, the peak current management circuit 216 looks up the current operating parameters from the temperature sensor 408B, voltage register 410B, and frequency register 412B to find a match in the operating voltage and operating frequency pairs along with the temperature band in which the current temperature stored in the temperature sensor 408B resides. The combination of those current operating parameters returns an indication of whether or not (shown as ON or OFF) the GPU 206 should be throttled to reduce current demand by the GPU 206 on the shared power rail 116.

FIG. 6C shows an exemplary filter LUT 608 configured to store whether to throttle the NPU 208 in FIG. 2 based on one or more current operating parameters of the NPU 208. The configuration and layout of the filter LUT 608 is the same as the filter LUTs 600 and 604 in FIGS. 6A and 6B. Operating parameters 610 include operating voltage, frequency pairs and temperature bands. The operating parameters 610 are shown to be the same as the operating parameters 602, 606 in the filter LUTs 600, 604, respectively, but could be different depending on the operating characteristics of the NPU 208. In operation, the peak current management circuit 216 looks up the current operating parameters from the temperature sensor 408C, voltage register 410C, and frequency register 412C to find a match in the operating voltage and operating frequency pairs along with the temperature band in which the current temperature stored in the temperature sensor 408C resides. The combination of those current operating parameters returns an indication of whether or not (shown as ON or OFF) the NPU 208 should be throttled to reduce current demand by the NPU 208 on the shared power rail 116.

The filter LUTs 600, 604, and 608 are programmable and may be programmed when a respective processing unit is initialized such as when the respective processing unit is powered on or is reset. Employing a filter LUT, such as the filter LUTs 600, 604, and 608 on a per processing unit basis, advantageously reduces signals, triggers, or events in the processor-based system 100.

FIGS. 7A-7C illustrate an exemplary mitigation LUT for each of the processing units (CPU 204, GPU 206, NPU 208) shown in FIG. 2, wherein the exemplary mitigation LUTs are configured to store mitigations of how to throttle the at least one of the plurality of processing units being indicated to be throttled in the filter LUTs 600, 604, 608 shown in FIGS. 6A-6C.

FIG. 7A shows an exemplary mitigation LUT 700 configured to store mitigations of how to throttle the CPU 204 in FIG. 2 based on one or more current operating parameters of the CPU 204. The configuration and layout of the mitigation LUT 700 is the same as the filter LUTs 600, 604 and 608 in FIGS. 6A-6C. Operating parameters 702 include operating voltage, frequency pairs and temperature bands. The operating parameters 702 are shown to be the same as those in the filter LUTs 600, 604 and 608 but could be different than those in the filter LUTs 600, 604 and 608 depending on the operating characteristics of the CPU 204. In operation, the CPU throttle circuit 218 looks up the current operating parameters from the temperature sensor 408A, voltage register 410A, and frequency register 412A to find a match in the operating voltage and operating frequency pairs along with the temperature band in which the current temperature stored in the temperature sensor 408A resides. The combination of those current operating parameters returns a mitigation for the CPU 204 to reduce the current demand by the CPU 204 on the shared power rail 116. For example, if the current voltage, frequency pair is V₁,f₁ and the CPU 204 is currently operating at 45° C., the mitigation would be to reduce the frequency of the clock driving the CPU 204 to 80% of the maximum frequency the CPU 204 may be clocked. In another example, if the current voltage, frequency pair is V₃,f₃ and the CPU 204 is currently operating at 45° C., the mitigation would be to utilize a conventional voltage/frequency reduction mitigation (“DCVS”) based on current operating parameters. For example, a method of determining a new operating point with an updated voltage and/or frequency of the CPU 204 for executing workloads could be a look-up table that has predefined voltage and/or frequency settings as a function of temperature or other factors. Generally, for example, voltage and/or frequency may be reduced as temperature increases to mitigate heat and reduce risk of circuit failure. As temperature decreases, the voltage and/or frequency may be increased for improved performance.

FIG. 7B shows an exemplary mitigation LUT 704 configured to store mitigations of how to throttle the GPU 206 in FIG. 2 based on one or more current operating parameters of the GPU 206. The configuration and layout of the mitigation LUT 704 is the same as the mitigation LUT 700 in FIG. 7A. Operating parameters 706 include operating voltage, frequency pairs and temperature bands. The operating parameters 706 are shown to be the same as those in the mitigation LUT 700 but could be different than those in the mitigation LUT 700 depending on the operating characteristics of the GPU 206. In operation, the GPU throttle circuit 220 looks up the current operating parameters from the temperature sensor 408B, voltage register 410B, and frequency register 412B to find a match in the operating voltage and operating frequency pairs along with the temperature band in which the current temperature stored in the temperature sensor 408B resides. The combination of those current operating parameters returns a mitigation for the GPU 206 to reduce the current demand by the GPU 206 on the shared power rail 116.

FIG. 7C shows an exemplary mitigation LUT 708 configured to store mitigations of how to throttle the NPU 208 in FIG. 2 based on one or more current operating parameters of the NPU 208. The configuration and layout of the mitigation LUT 708 is the same as the mitigation LUTs 700, 704 in FIGS. 7A and 7B. Operating parameters 710 include operating voltage, frequency pairs and temperature bands. The operating parameters 710 are shown to be the same as those in the mitigation LUTs 700, 704 but could be different than those in the mitigation LUTs 700, 704 depending on the operating characteristics of the NPU 208. In operation, the NPU throttle circuit 222 looks up the current operating parameters from the temperature sensor 408C, voltage register 410C, and frequency register 412C to find a match in the operating voltage and operating frequency pairs along with the temperature band in which the current temperature stored in the temperature sensor 408C resides. The combination of those current operating parameters returns a mitigation for the NPU 208 to reduce the current demand by the NPU 208 on the shared power rail 116.

The mitigation LUTs 700, 704, and 708 are programmable and may be programmed when a respective processing unit is initialized such as when the respective processing unit is powered on or is reset. Employing a mitigation LUT, such as the mitigation LUTs 700, 704, and 708 on a per processing unit basis, advantageously enables reducing a specific processing unit's current demand on the shared power rail 116 based on specific workloads running in the processor-based system 100. For example, a gaming workload would impact a GPU more intensely than a CPU or an NPU. Mitigation LUTs may be programmed to ensure that, for the same current operating parameters between a GPU, CPU and NPU, the CPU and/or NPU would be throttled when the GPU is not.

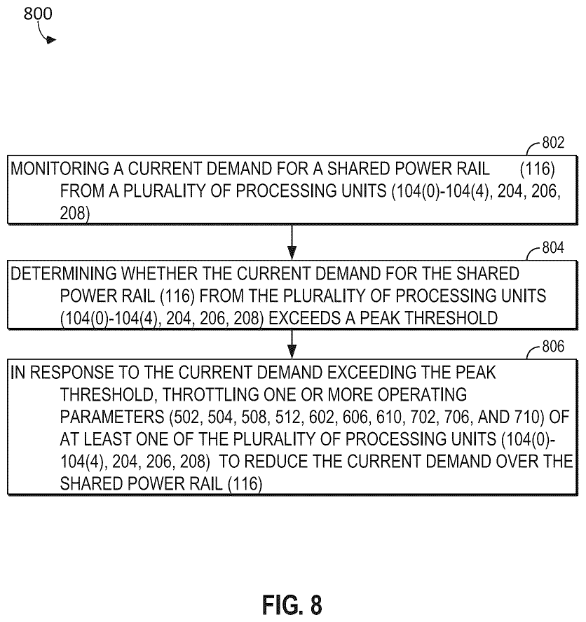

FIG. 8 is a flowchart illustrating an exemplary process 800 for dynamically mitigating peak current demand of a shared power rail powering a memory system, wherein the memory system is deployed in a processor-based system including the processor-based system 100 in FIG. 1. In this regard, a first exemplary step in the process 800 of FIG. 8 may include monitoring a current demand for the shared power rail 116 from a plurality of processing units 104(0)-104(4), 204, 206, 208 (block 802, FIG. 8). A next step in the process 400 may include determining whether the current demand for the shared power rail 116 from the plurality of processing units 104(0)-104(4), 204, 206, 208 exceeds a peak threshold (block 804, FIG. 8). A next step in the process 400 may include, in response to the current demand exceeding the peak threshold, throttling one or more operating parameters 502, 504, 508, 512, 602, 606, 610, 702, 706, and 710 of at least one of the plurality of processing units 104(0)-104(4), 204, 206, 208 to reduce the current demand over the shared power rail 116 (block 806, FIG. 8).

Electronic devices that include a processor-based system that includes the processor-based system 100 in FIG. 1 which is configured to dynamically mitigate peak current demand of a shared power rail powering a memory system as disclosed in aspects described herein may be provided in or integrated into any processor-based device where a memory system is powered by a shared power rail. Examples, without limitation, include an extended reality (XR) device including, but not limited to, smart glass and artificial intelligence (AI) pins, a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, and a vehicle component.

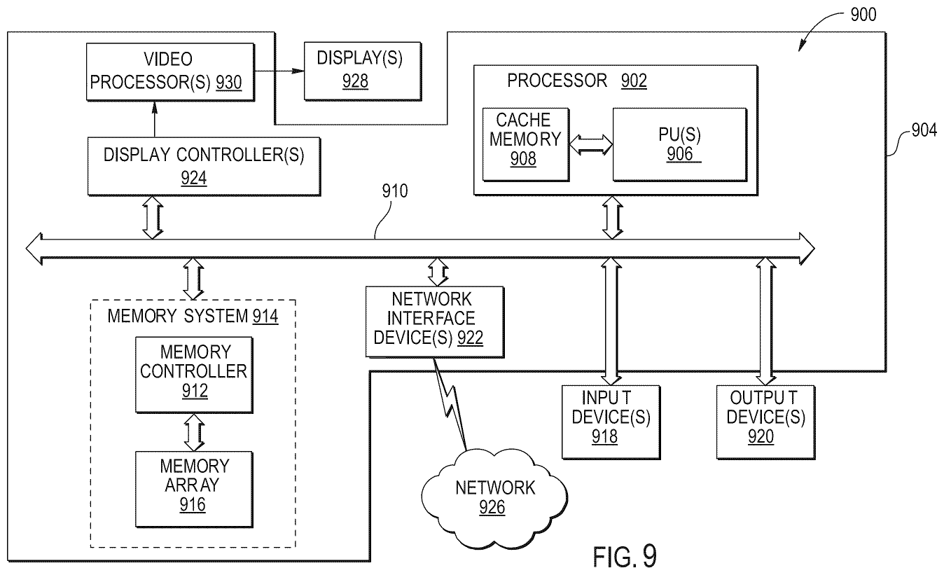

In this regard, FIG. 9 is a block diagram of an exemplary processor-based system 900 that can include a processor-based system including, but not limited to, the processor-based system 100 of FIG. 1 and according to the exemplary process 800 of FIG. 8 which is configured to dynamically mitigate peak current demand of a shared power rail powering a memory system.

In this example, the processor-based system 900 includes a processor 902 deployed on a semiconductor die 904 wherein the processor-based system 900 includes one or more processing units (captioned as “PUs” in FIG. 9) 906 which are configured to dynamically mitigate peak current demand of a shared power rail powering a memory system as disclosed herein and, which may also be referred to as cores or processor cores. The processor 902 may have cache memory 908 coupled to the processor 902 for rapid access to temporarily stored data. The processor 902 is coupled to a system bus 910 and can intercouple server and client devices included in the processor-based system 900. As is well known, the processor 902 communicates with these other devices by exchanging address, control, and data information over the system bus 910. For example, the processor 902 can communicate bus transaction requests to a memory controller 912, as an example of a client device. Although not illustrated in FIG. 9, multiple system buses 910 could be provided, wherein each system bus 910 constitutes a different fabric.

Other server and client devices can be connected to the system bus 910 and deployed in the semiconductor die 904 wherein the processor-based system 900 is configured to dynamically mitigate peak current demand of a shared power rail powering a memory system as disclosed herein and includes one or more central processing units. As illustrated in FIG. 9, these devices can include a memory system 914 that includes the memory controller 912 and a memory array(s) 916, one or more input devices 918, one or more output devices 920, one or more network interface devices 922, and one or more display controllers 924, as examples. The input device(s) 918 can include any type of input device, including but not limited to input keys, switches, voice processors, etc. The output device(s) 920 can include any type of output device, including, but not limited to, audio, video, other visual indicators, etc. The network interface device(s) 922 can be any device configured to allow exchange of data to and from a network 926. The network 926 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 922 can be configured to support any type of communications protocol desired.

The processor 902 may also be configured to access the display controller(s) 924 over the system bus 910 to control information sent to one or more displays 928. The display controller(s) 924 sends information to the display(s) 928 to be displayed via one or more video processors 930, which process the information to be displayed into a format suitable for the display(s) 928. The display controller(s) 924 and/or the video processors 930 may comprise or be integrated into a GPU. The display(s) 928 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. A processor-based system, comprising:
a memory system;
a shared power rail configured to:
   supply power to the memory system; and
a plurality of processing units, each of the plurality of processing units configured to access the memory system;
the processor-based system configured to:
   monitor a current demand for the shared power rail from the plurality of processing units;
   determine whether the current demand for the shared power rail exceeds a peak threshold; and
   in response to the current demand exceeding the peak threshold, throttle one or more operating parameters of at least one of the plurality of processing units to reduce the current demand over the shared power rail.
      2. The processor-based system of clause 1, further comprising:
a power management integrated circuit (PMIC) coupled to the memory system through the shared power rail,
wherein:
   the processor-based system configured to monitor the current demand for the shared power rail from the plurality of processing units further comprises:
      the PMIC, further configured to:
         measure the current demand on the shared power rail.
            3. The processor-based system of clause 1 or 2, further comprising:
a power meter circuit,
wherein:
   the processor-based system configured to monitor the current demand for the shared power rail from the plurality of processing units further comprises:
      the power meter circuit, configured to:
         estimate the current demand on the shared power rail.
            4. The processor-based system of clause 3, further comprising:
an estimation look-up table (LUT) configured to store an estimated current demand for each of the plurality of processing units based on one or more current operating parameters for each of the plurality of processing units, the one or more current operating parameters selected from a group consisting of operating voltage, operating frequency, and current temperature of the plurality of processing units, wherein: the power meter circuit configured to estimate the current demand for the
   shared power rail is further configured to:
   look up the estimated current demand stored in the estimation LUT based on the one or more current operating parameters.
      5. The processor-based system of clause 3 or 4, wherein:
the power meter circuit further comprises:
   a polynomial circuit configured to calculate an estimated current demand based on one or more current operating parameters for each of the plurality of processing units, the one or more current operating parameters selected from a group consisting of operating voltage, operating frequency, and current temperature of the plurality of processing units, wherein:
      the power meter circuit configured to estimate the current demand for the shared power rail is further configured to:
         input the one or more current operating parameters to the polynomial circuit to calculate the current demand.
            6. The processor-based system of any of clauses 1-5, wherein:
the processor-based system configured to, in response to the current demand exceeding the peak threshold, throttle the one or more operating parameters of the at least one of the plurality of processing units to reduce the current demand over the shared power rail, is further configured to:
   determine whether the one or more operating parameters of the at least one of the plurality of processing units should be throttled;
   in response to the one or more operating parameters of the at least one of the plurality of processing units being determined to be throttled, set the one or more operating parameters of the at least one of the plurality of processing units being determined to be throttled to a reduced level based on current operating parameters of the at least one of the plurality of processing units.
      7. The processor-based system of clause 6, further comprising:
a filter look-up table (LUT) configured to store whether to throttle one or more of the plurality of processing units based on one or more current operating parameters for each of the plurality of processing units, the one or more current operating parameters selected from a group consisting of an operating voltage, an operating frequency, and a current temperature of the plurality of processing units, wherein:
   the processor-based system configured to determine whether to throttle one or more of the plurality of processing units is further configured to:
      look up a plurality of indications stored in the filter LUT corresponding to the plurality of processing units based on the one or more current operating parameters for each of the plurality of processing units, the plurality of indications indicating whether to throttle the at least one of the plurality of processing units.
         8. The processor-based system of clause 7, wherein:
the processor-based system further comprises:
   a plurality of throttle circuits corresponding to the plurality of processing units; and
   a mitigation LUT configured to store a plurality of mitigations of how to throttle the at least one of the plurality of processing units being indicated to be throttled in the filter LUT based on the one or more current operating parameters corresponding to the at least one of the plurality of processing units, the one or more current operating parameters selected from the group consisting of the operating voltage, the operating frequency, and the current temperature of the plurality of processing units,
   wherein:
      in response to the at least one of the plurality of processing units being indicated to be throttled based on the one or more current operating parameters in the filter LUT, the processor-based system is further configured to:
         trigger at least one of the plurality of throttle circuits corresponding to the at least one of the plurality of processing units being indicated to be throttled;
      in response to the at least one of the plurality of throttle circuits being triggered, the at least one of the plurality of throttle circuits is configured to:
         look up a mitigation in the mitigation LUT corresponding to a processing unit of the at least one of the plurality of processing units being indicated to be throttled based on the one or more current operating parameters for the processing unit.
            9. The processor-based system of any of clauses 1-8, wherein:
the plurality of processing units comprises at least one central processing unit, at least one graphics processing unit, and at least one neural processing unit.
   10. The processor-based system of any of clauses 1-9, wherein:
the processor-based system is an extended reality device.
   11. A method for dynamically mitigating peak current demand of a shared power rail powering a memory system, comprising:
monitoring a current demand for the shared power rail from a plurality of processing units;
determining whether the current demand for the shared power rail from the plurality of processing units exceeds a peak threshold; and
in response to the current demand exceeding the peak threshold, throttling one or more operating parameters of at least one of the plurality of processing units to reduce the current demand over the shared power rail.
   12. The method of clause 11, wherein:
monitoring the current demand for the shared power rail from the plurality of processing units comprises:
   measuring the current demand on the shared power rail.
      13. The method of clause 11 or 12 wherein:
monitoring the current demand for the shared power rail from the plurality of processing units comprises:
   estimating the current demand for the shared power rail.
      14. The method of clause 13, wherein:
monitoring the current demand for the shared power rail from the plurality of processing units comprises:
   storing an estimated current demand for each of the plurality of processing units based on one or more current operating parameters for each of the plurality of processing units, the one or more current operating parameters selected from a group consisting of operating voltage, operating frequency, and current temperature of the plurality of processing units; and
   looking up the estimated current demand based on the one or more current operating parameters.
      15. The method of clause 13 or 14, wherein:
monitoring the current demand for the shared power rail from the plurality of processing units comprises:
   inputting one or more current operating parameters for each of the plurality of processing units, the one or more current operating parameters selected from a group consisting of operating voltage, operating frequency, and current temperature of the plurality of processing units to a polynomial circuit; and
   calculating an estimated current demand utilizing the polynomial circuit based on the one or more current operating parameters.
      16. The method of any of clauses 11-15, wherein:
in response to the current demand exceeding the peak threshold, throttling the one or more operating parameters of at least one of the plurality of processing units to reduce the current demand over the shared power rail comprises:
   determining whether the one or more operating parameters of the at least one of the plurality of processing units should be throttled;
   in response to the one or more operating parameters of the at least one of the plurality of processing units being determined to be throttled, setting the one or more operating parameters of the at least one of the plurality of processing units being determined to be throttled to a reduced level based on current operating parameters of the at least one of the plurality of processing units.
      17. The method of clause 16, wherein:
determining whether the one or more operating parameters of the at least one of the plurality of processing units should be throttled comprises:
   storing a plurality of indications indicating whether to throttle one or more of the plurality of processing units in a filter look-up table (LUT) based on one or more current operating parameters for each of the plurality of processing units, the one or more current operating parameters selected from a group consisting of an operating voltage, an operating frequency, and a current temperature of the plurality of processing units; and
   looking up the plurality of indications stored in the filter LUT corresponding to the plurality of processing units based on the one or more current operating parameters for each of the plurality of processing units, the plurality of indications indicating to throttle the at least one of the plurality of processing units.
      18. The method of clause 17, wherein:
setting the one or more operating parameters of the at least one of the plurality of processing units being determined to be throttled to the reduced level based on the current operating parameters of the at least one of the plurality of processing units comprises:
   triggering at least one of a plurality of throttle circuits corresponding to the at least one of the plurality of processing units being indicated to be throttled;
   in response to the at least one of the plurality of throttle circuits being triggered, looking up a mitigation in a mitigation LUT corresponding to a processing unit of the at least one of the plurality of processing units being indicated to be throttled based on the one or more current operating parameters for the processing unit, the mitigation specifying the reduced level to which to set the current operating parameters.

What is claimed is:

1. A processor-based system, comprising:
a memory system;
a shared power rail configured to:
supply power to the memory system; and
a plurality of processing units, each of the plurality of processing units configured to access the memory system;
the processor-based system configured to:
monitor a current demand for the shared power rail from the plurality of processing units;
determine whether the current demand for the shared power rail exceeds a peak threshold; and
in response to the current demand exceeding the peak threshold, throttle one or more operating parameters of at least one of the plurality of processing units to reduce the current demand over the shared power rail.

2. The processor-based system of claim 1, further comprising:
a power management integrated circuit (PMIC) coupled to the memory system through the shared power rail,
wherein:
the processor-based system configured to monitor the current demand for the shared power rail from the plurality of processing units further comprises:
the PMIC, further configured to:
measure the current demand on the shared power rail.

3. The processor-based system of claim 1, further comprising:
a power meter circuit,
wherein:
the processor-based system configured to monitor the current demand for the shared power rail from the plurality of processing units further comprises:
the power meter circuit, configured to:
estimate the current demand on the shared power rail.

4. The processor-based system of claim 3, further comprising:
an estimation look-up table (LUT) configured to store an estimated current demand for each of the plurality of processing units based on one or more current operating parameters for each of the plurality of processing units, the one or more current operating parameters selected from a group consisting of operating voltage, operating frequency, and current temperature of the plurality of processing units, wherein:
the power meter circuit configured to estimate the current demand for the shared power rail is further configured to:
look up the estimated current demand stored in the estimation LUT based on the one or more current operating parameters.

5. The processor-based system of claim 3, wherein:
the power meter circuit further comprises:
a polynomial circuit configured to calculate an estimated current demand based on one or more current operating parameters for each of the plurality of processing units, the one or more current operating parameters selected from a group consisting of operating voltage, operating frequency, and current temperature of the plurality of processing units, wherein:
the power meter circuit configured to estimate the current demand for the shared power rail is further configured to:
input the one or more current operating parameters to the polynomial circuit to calculate the current demand.

6. The processor-based system of claim 1, wherein:
the processor-based system configured to, in response to the current demand exceeding the peak threshold, throttle the one or more operating parameters of the at least one of the plurality of processing units to reduce the current demand over the shared power rail, is further configured to:
determine whether the one or more operating parameters of the at least one of the plurality of processing units should be throttled;
in response to the one or more operating parameters of the at least one of the plurality of processing units being determined to be throttled, set the one or more operating parameters of the at least one of the plurality of processing units being determined to be throttled to a reduced level based on current operating parameters of the at least one of the plurality of processing units.

7. The processor-based system of claim 6, further comprising:
a filter look-up table (LUT) configured to store whether to throttle one or more of the plurality of processing units based on one or more current operating parameters for each of the plurality of processing units, the one or more current operating parameters selected from a group consisting of an operating voltage, an operating frequency, and a current temperature of the plurality of processing units, wherein:
the processor-based system configured to determine whether to throttle one or more of the plurality of processing units is further configured to:
look up a plurality of indications stored in the filter LUT corresponding to the plurality of processing units based on the one or more current operating parameters for each of the plurality of processing units, the plurality of indications indicating whether to throttle the at least one of the plurality of processing units.

8. The processor-based system of claim 7, wherein:
the processor-based system further comprises:
a plurality of throttle circuits corresponding to the plurality of processing units; and
a mitigation LUT configured to store a plurality of mitigations of how to throttle the at least one of the plurality of processing units being indicated to be throttled in the filter LUT based on the one or more current operating parameters corresponding to the at least one of the plurality of processing units, the one or more current operating parameters selected from the group consisting of the operating voltage, the operating frequency, and the current temperature of the plurality of processing units,
wherein:
in response to the at least one of the plurality of processing units being indicated to be throttled based on the one or more current operating parameters in the filter LUT, the processor-based system is further configured to:
trigger at least one of the plurality of throttle circuits corresponding to the at least one of the plurality of processing units being indicated to be throttled;
in response to the at least one of the plurality of throttle circuits being triggered, the at least one of the plurality of throttle circuits is configured to:
look up a mitigation in the mitigation LUT corresponding to a processing unit of the at least one of the plurality of processing units being indicated to be throttled based on the one or more current operating parameters for the processing unit.

9. The processor-based system of claim 1, wherein:
the plurality of processing units comprises at least one central processing unit, at least one graphics processing unit, and at least one neural processing unit.

10. The processor-based system of claim 1, wherein:
the processor-based system is an extended reality device.

11. A method for dynamically mitigating peak current demand of a shared power rail powering a memory system, comprising:
monitoring a current demand for the shared power rail from a plurality of processing units;
determining whether the current demand for the shared power rail from the plurality of processing units exceeds a peak threshold; and
in response to the current demand exceeding the peak threshold, throttling one or more operating parameters of at least one of the plurality of processing units to reduce the current demand over the shared power rail.

12. The method of claim 11, wherein:
monitoring the current demand for the shared power rail from the plurality of processing units comprises:
measuring the current demand on the shared power rail.

13. The method of claim 11, wherein:
monitoring the current demand for the shared power rail from the plurality of processing units comprises:
estimating the current demand for the shared power rail.

14. The method of claim 13, wherein:
monitoring the current demand for the shared power rail from the plurality of processing units comprises:
storing an estimated current demand for each of the plurality of processing units based on one or more current operating parameters for each of the plurality of processing units, the one or more current operating parameters selected from a group consisting of operating voltage, operating frequency, and current temperature of the plurality of processing units; and
looking up the estimated current demand based on the one or more current operating parameters.

15. The method of claim 13, wherein:
monitoring the current demand for the shared power rail from the plurality of processing units comprises:
inputting one or more current operating parameters for each of the plurality of processing units, the one or more current operating parameters selected from a group consisting of operating voltage, operating frequency, and current temperature of the plurality of processing units to a polynomial circuit; and
calculating an estimated current demand utilizing the polynomial circuit based on the one or more current operating parameters.

16. The method of claim 11, wherein:
in response to the current demand exceeding the peak threshold, throttling the one or more operating parameters of at least one of the plurality of processing units to reduce the current demand over the shared power rail comprises:
determining whether the one or more operating parameters of the at least one of the plurality of processing units should be throttled;
in response to the one or more operating parameters of the at least one of the plurality of processing units being determined to be throttled, setting the one or more operating parameters of the at least one of the plurality of processing units being determined to be throttled to a reduced level based on current operating parameters of the at least one of the plurality of processing units.

17. The method of claim 16, wherein:
determining whether the one or more operating parameters of the at least one of the plurality of processing units should be throttled comprises:
storing a plurality of indications indicating whether to throttle one or more of the plurality of processing units in a filter look-up table (LUT) based on one or more current operating parameters for each of the plurality of processing units, the one or more current operating parameters selected from a group consisting of an operating voltage, an operating frequency, and a current temperature of the plurality of processing units; and
looking up the plurality of indications stored in the filter LUT corresponding to the plurality of processing units based on the one or more current operating parameters for each of the plurality of processing units, the plurality of indications indicating to throttle the at least one of the plurality of processing units.

18. The method of claim 17, wherein:
setting the one or more operating parameters of the at least one of the plurality of processing units being determined to be throttled to the reduced level based on the current operating parameters of the at least one of the plurality of processing units comprises:
triggering at least one of a plurality of throttle circuits corresponding to the at least one of the plurality of processing units being indicated to be throttled;
in response to the at least one of the plurality of throttle circuits being triggered, looking up a mitigation in a mitigation LUT corresponding to a processing unit of the at least one of the plurality of processing units being indicated to be throttled based on the one or more current operating parameters for the processing unit, the mitigation specifying the reduced level to which to set the current operating parameters.
